(19) United States
(12) Patent Application Publication
(10) Pub. No.: US 2024/0302650 A1
(43) Pub. Date: Sep. 12, 2024

(54) Method for Symmetrizing Single-Sided Pump Laser Profiles

(71) Applicant: L3Harris Technologies, Inc., Melbourne, FL (US)

(72) Inventors: William J. HUBBARD, Meredith, NH (US); William J. GORVEATT, Londonderry, NH (US); Alan E. TOBEY, Billerica, MA (US)

(21) Appl. No.: 18/179,442

(22) Filed: Mar. 7, 2023

(51) Int. Cl. G02B 27/00; G01S 7/481; G01S 17/08; G06F 30/10; H01S 3/0941

(52) U.S. Cl. CPC G02B 27/0012; G06F 30/10; G01S 7/4814; G01S 17/08; H01S 3/0941

(57) ABSTRACT

A method for making a single-sided pumped laser device may include determining initial relative spacings of a reflector with respect to a laser medium body having a known absorption coefficient, and to a laser pump having known divergence angles of pump light to be directed at a side of the laser medium body. A merit function defining a desired absorption profile of the pump light passing through the laser medium body may be determined. An optical model may be operated based on the merit function and the determined absorption coefficient, divergence angles and initial relative spacings to determine a curvature of the reflector, and adjusted relative spacings among the laser medium body, the laser pump, and the reflector. The laser medium body, the laser pump, and the reflector may be assembled according to the determined curvature of the at least one reflector and the adjusted relative spacings to make the single-sided pumped laser device having a symmetrical absorption profile.

### TECHNICAL FIELD

The present disclosure relates to laser devices, and more particularly, to a method for making a single-sided pumped laser device having a symmetrical absorption pump profile within a laser medium body.

### BACKGROUND

Laser devices have grown in usefulness, particularly in industrial, medical and military applications. Diode pumped laser devices are power efficient and solid-state with a long shelf-life.

Laser devices may be single pumped on one side of the laser medium body, or double pumped along multiple axes of the laser medium body to increase radial symmetry. A single pumped laser device as compared to a double pumped laser device is more cost efficient since less components are required.

However, a drawback of a single pumped laser device is that the pump light distribution within the laser medium body can lead to an asymmetric pattern relative to a centerline (i.e., longitudinal axis) of the laser medium body. Asymmetry of the pump light distribution within the laser medium body can be inefficient and lead to sub-optimal laser mode performance.

### SUMMARY

A method for making a single-sided pumped laser device may include determining an absorption coefficient for a laser medium body, determining divergence angles of pump light from a laser pump to be directed at a side of the laser medium body, and determining initial relative spacings of at least one reflector for the pump light with respect to the laser medium body and the laser pump. A merit function defining a desired absorption profile of the pump light passing through the laser medium body may be generated. The method may further include using a processor and an associated memory to operate an optical model based on the merit function and the determined pump light absorption coefficient, divergence angles and initial relative spacings to determine a curvature of the at least one reflector, and adjusted relative spacings among the laser medium body, the laser pump, and the at least one reflector. The laser medium body, the laser pump, and the at least one reflector may be assembled according to the determined curvature of the at least one reflector and the adjusted relative spacings to make the single-sided pumped laser device.

The merit function may include a plurality of target absorption values defining the desired absorption profile.

The optical model may determine a plurality of computed absorption profiles, with each computed absorption profile comprising a plurality of computed absorption values corresponding to the plurality of target absorption values.

The optical model may determine the plurality of computed absorption profiles while varying curvature of the at least one reflector and varying relative spacings among the laser medium body, the laser pump and the at least one reflector.

The merit function may compare, for each computed absorption profile, the plurality of computed absorption values to the plurality of target absorption values.

The merit function may determine, for each computed absorption profile, a difference between the plurality of computed absorption values and the corresponding plurality of target absorption values, with the differences for each computed absorption profile being summed together to define a respective merit function value.

The optical model may define a plurality of respective merit function values ranging from high to low, with the single-sided pumped laser device being assembled using the curvature of the at least one reflector and the relative spacings among the laser medium body, the laser pump and the at least one reflector for the merit function value having the lowest value.

The laser pump may include a laser diode. The laser medium body may include one of a laser rod having a cylindrical shape and a laser slab having a rectangular shape.

The single-sided pumped laser device may be configured to operate within a laser range finder. The desired absorption profile may be symmetrical to a centerline of the laser medium body.

Yet another aspect is directed to a non-transitory computer readable medium for operating a computing device comprising a display and processor coupled to the display, and with the non-transitory computer readable medium having a plurality of computer executable instructions for causing the processor to perform steps as described above.

### BRIEF DESCRIPTION OF THE DRAWINGS

FIG. 1A is a schematic block diagram side view of a single-sided pumped laser device in which various aspects of the disclosure may be implemented.

FIG. 1B is a schematic block diagram end view of the single-sided pumped laser device illustrated in FIG. 1A.

FIG. 2 is a flow diagram on a method for making the single-sided pumped laser device illustrated in FIGS. 1A and 1B.

FIG. 3 is a schematic block diagram of a laser pump cavity for the single-sided pumped laser device illustrated in FIGS. 1A and 1B with additional reflector configurations.

FIG. 4 is a plot of normalized intensity for forward and backward round-trip propagation within the laser medium body illustrated in FIG. 3.

FIG. 5 is a plot showing a figure-of-merit for asymmetric laser pump absorption within the laser medium body illustrated in FIG. 3.

FIG. 6 is a plot showing the pump energy absorbed versus a number of round-trips through the laser medium body illustrated in FIG. 3.

FIG. 7 is a cross-sectional view of the laser medium body illustrated in FIG. 3 depicting a radially-symmetric and intensity varying pump mode.

FIG. 8 is a schematic block diagram of the resonator components to be used by the optical model for the single-sided pumped laser device illustrated in FIGS. 1A and 1B.

FIG. 9 is a plot of the absorbed flux for the laser medium body illustrated in FIG. 8 after operating the optical model based on the merit function.

### DETAILED DESCRIPTION

The present description is made with reference to the accompanying drawings, in which exemplary embodiments are shown. However, many different embodiments may be used, and thus the description should not be construed as limited to the particular embodiments set forth herein. Rather, these embodiments are provided so that this disclosure will be thorough and complete. Like numbers refer to like elements throughout, and prime notations may be used to indicate similar elements in different embodiments.

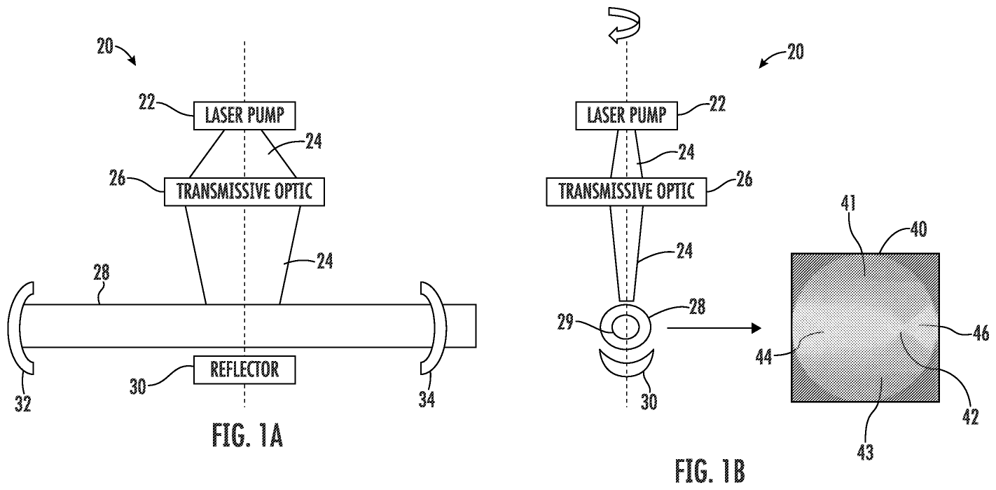

Referring initially to FIGS. 1A and 1B, a single-sided pumped laser device 20 will be discussed. A side view of the single-sided pumped laser device 20 is in FIG. 1A, and a corresponding end view is in FIG. 1B. The end view is along a longitudinal axis of the laser medium body 28. The laser medium body 28 is configured as a rod having a cylindrical shape. Alternatively, the laser medium body 28 may be configured as a slab having a rectangular shape.

The single-sided pumped laser device 20 includes a laser pump 22 that emits pump light 24 towards the laser medium body 28. The laser pump 22 may be configured as a laser diode that transfers energy into the laser medium body 28. The energy is absorbed in the laser medium body 28, and produces excited states in its dopant atoms. When the number of particles in one excited state exceeds the number of particles in the ground state or a less-excited state, population inversion is achieved. In this condition, a stimulated emission can take place and the laser medium body 28 acts as a laser. The power of the laser pump 22 needs to be sufficient to achieve the lasing threshold of the laser.

The pump light 24 may pass through an optional transmissive optic or lens 26 that redirects the pump light 24 towards the laser medium body 28. Based on an absorption coefficient of the laser medium body 28, the pump light 24 is partially absorbed. The pump light 24 that is not absorbed passes through the laser medium body 28, and is received by at least one reflector 30. The reflector 30 reflects the received pump light back into the laser medium body 28. On one end of the laser medium body 28 is a high-reflectance mirror 32, and on the opposite end is an output coupler 34.

In an example embodiment, the single-sided pumped laser device 20 may be configured to operate within a hand-held laser rangefinder. Since the single-sided pumped laser device 20 is single pumped as compared to double pumped, it is ideal from a cost-savings standpoint since less components are required. However, a drawback of a single-sided pumped laser device is that the laser mode (i.e., pump light distribution) within the laser medium body 28 can lead to an asymmetric pattern relative to a centerline (i.e., longitudinal axis) of the laser medium body 28. A representation of a cross-sectional view 40 of the laser medium body 28 illustrates an asymmetrical pump light distribution pattern within a transverse plane along the longitudinal axis.

Within the cross-sectional view 40 of the laser medium body 28, pump irradiance has the highest concentration at point 42 which is not radially centered within the laser medium body 28. Pump irradiance is the flux of radiant energy per unit area that is normal to the direction of flow of radiant energy through the laser medium body 28. The concentration of pump irradiance gradually reduces but continues throughout sections 44 and 46, whereas the concentration of pump irradiance in sections 41 and 43 is close to zero.

Asymmetry of the pump light distribution within the laser medium body 28 can lead to inefficiency and sub-optimal laser mode performance through thermal-optic distortions (thermal wedge) and deleterious spatial pumping outside of the desired laser mode 22. A profile of the pump light distribution appears as an asymmetrical bow tie shape within the cross-sectional view 40 of the laser medium body 28.

Asymmetry of the pump light distribution also produces and selectively distributes waste heat in unwanted regions within the laser medium. Pump irradiance excites the ions within the laser medium body 28. As pump laser excitation occurs, mechanical stresses are introduced within the laser medium body 28. As the laser medium body 28 heats up, its properties change. This causes a thermo-optical wedge where it would emulate a wedged laser medium body 28. The effective wedge prism bends the laser beam within the laser medium body and therefore misaligns a resonant laser cavity 28 instead of allowing the laser beam to oscillate along a predetermined aligned path. This in turn causes misalignment with the high-reflectance mirror 32 and the output coupler 34.

As will be discussed in greater detail below, a method for symmetrizing pump light distribution within the single-sided pumped laser device 20 is provided. An optical model, such as Zemax OpticStudio®, is used to model a profile of the pump light distribution based on the resonator components within the single-sided pumped laser device 20. The resonator components include all of the elements illustrated in the single-sided pumped laser device 20. The optical model uses a merit function to correct for pump light distribution asymmetry by determining component tilts, spacings and surface shape modifications of the resonator components within the single-sided pumped laser device 20.

The merit function includes target absorption values defining a desired symmetrical absorption profile representing an absorbed flux of the laser beam passing through the laser medium body 28. The optical model determines a plurality of computed absorption profiles, with each computed absorption profile comprising a plurality of computed absorption values corresponding to the plurality of target absorption values. The plurality of computed absorption profiles are determined while varying curvature of the reflector 30 and varying relative spacings and tilts among the laser medium body 28, the laser pump 22 and the at least one reflector 30.

The optical model iteratively computes the absorption values using different permutations of tilts, spacings, index of refractions, and surface shape modifications of the resonator components. The single-sided pumped laser device 20 is assembled using the tilts, spacings and surface shape modifications of the resonator components that generate a computed absorption profile that more closely matches the desired absorption profile.

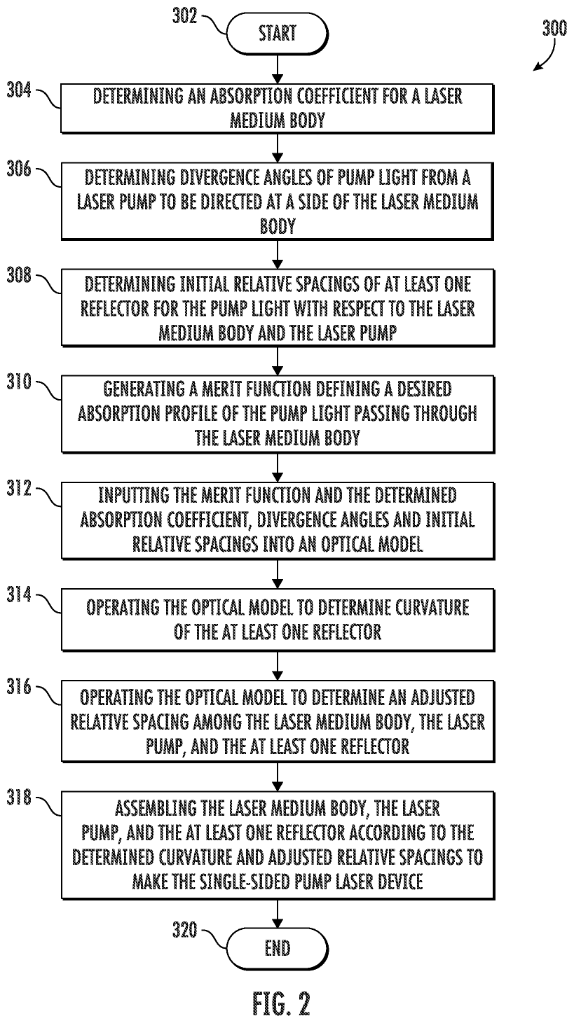

Referring now to FIG. 2, a flow diagram 300 on a method for making the single-sided pumped laser device 20 will be discussed. From the start (Block 302), a laser absorption coefficient is determined at Block 304 for the laser medium body 28. The laser absorption coefficient describes the intensity attenuation of light passing through a material.

The laser medium width-normalized absorption coefficient (herein after referred to as absorption coefficient) ranges from 0 to infinity. A laser absorption coefficient of infinity means all of the energy of the pump light 24 from the laser pump 22 is absorbed by the laser medium body 28, whereas a laser absorption coefficient of 0 means that all of the energy of the pump light 24 passes through the laser medium body 28. For discussion purposes, the laser absorption coefficient is 0.5 for the laser medium body 28.

Divergence angles of the beam (i.e., pump light 24) from the laser pump 22 to be directed at a side of the laser medium body 28 is determined at Block 306. Beam divergence is an angular measure of the increase in beam diameter or radius with distance from the optical aperture from which the beam was emitted. A laser diode, for example, emits pump light 24 having an elliptical cross-section shape. The y-axis with a large divergence angle is called the fast axis, and the x-axis with a smaller divergence angle is called the slow axis.

Initial relative spacings of the reflector 30 with respect to the laser medium body 28 and the laser pump 22 are determined at Block 308. The initial relative spacings is a starting point. When the single-sided pumped laser device 20 is configured to operate within a laser rangefinder, for example, the initial relative spacings are based on what would be permitted within the intended size or dimensions of the laser rangefinder.

A merit function is generated at Block 310 to define a desired absorption profile of the pump light 24 passing through the laser medium body 28. The desired absorption profile is symmetrical relative to a centerline of the laser medium body 28. As will be discussed in greater detail below, the merit function comprises a plurality of target absorption values defining the desired absorption profile.

At Block 312, the merit function and the determined absorption coefficient, divergence angles and initial relative spacings are input into the optical model. A computing device comprising a processor and an associated memory is operated at Block 314 to determine a curvature of the reflector 30 and at Block 316 to determine adjusted relative spacings among the laser medium body 28, the laser pump 22, and the reflector 30. If the single-sided pumped laser device 20 includes the optional transmissive optic 26, then the curvature of the transmissive optic 26 would also be determined, as well as determining adjusted relative spacings taking into account the transmissive optic 26.

The laser medium body 28, the laser pump 22, and the reflector 30 are assembled at Block 318 according to the determined curvature of the reflector and the adjusted relative spacings to make the single-sided pumped laser device. Example curvatures and spacings will be discussed in more detail below. The method ends at Block 320.

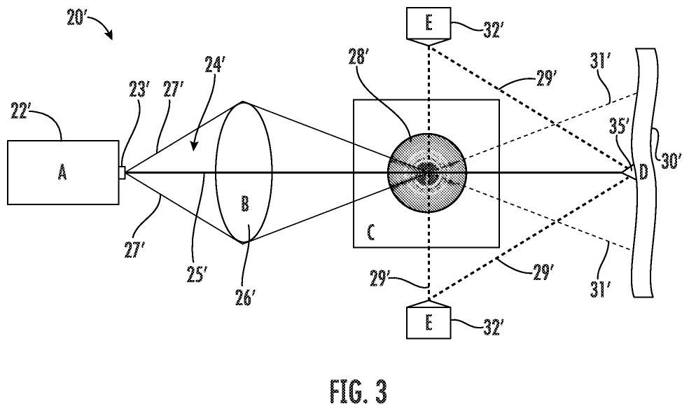

Referring now to FIG. 3, a single-sided pumped laser device 20′ with additional reflectors will be discussed in greater detail. An axis of the laser beam is along the longitudinal axis of the laser medium body 28′ (axis is not shown as it project into and out of the page), and is located at the confluence of the solid and dotted lines. The cross-sectional view of the laser medium body C depicts a radially-symmetric and intensity varying pump mode.

The block labeled A is the laser pump 22′ with an emitter element 23′ providing the pump light 24′. Optic element B is a transmissive optic 26′ that redirects the pump light 24′ output from the emitter element 23′ into the laser medium body 28′. The laser medium body 28′ is labeled element C.

The pump light 24′ that passes through the laser medium body 28′ is reflected by reflector D, which is the main reflector 30′ for recirculating the pump light within the laser medium body 28′. Reflector D may have an arbitrary shape, such as continuous or discrete freeform shapes.

Reflector D includes a triangle reflector point 35′ so that a portion of the reflected pump light is directed to ancillary reflectors E instead of directly back into the laser medium body 28′. The ancillary reflectors E are optional, and may also be referred to as ancillary reflectors 32′. The ancillary reflectors E may likewise have an arbitrary shape.

The pump laser axis corresponds to the solid line 25′ that travels from the emitter element 23′ through the transmissive optic element B and the laser medium body C to be reflected by the triangle reflector point 35′ on reflector D. The solid lines 27 indicate marginal rays or pump angular extent. The dashed lines 29 and the dashed lines 31 indicate notional pump recirculation paths.

A desired characteristic of the pump profile formed within the laser medium body C is to be radially-symmetric, and to overlap spatially with the desired laser mode. The pump profile refers to the distribution of energy within the laser medium body C.

A desired laser mode is the fundamental transverse mode which is designated as TEM₀₀, where the subscript 00 indicates a continuous beam profile without nodes. TEM stands for transverse electromagnetic and refers to the form of the standing waves. The TEM₀₀ mode has a bell-shaped Gaussian curve.

The pump laser mode refers to the distribution of the pump light within the laser medium body C. The distribution of the pump light is desired to be transversely symmetrical to a centerline of the laser medium body C. As noted above, asymmetry of the pump light distribution within the laser medium body C can lead to inefficiency and sub-optimal laser mode performance. To provide optimal efficiency, a profile of the pump mode is to spatially overlap a profile of the resultant spatial distribution for the laser mode.

The laser pump A is selected and characterized such that its divergence properties are known. Transmissive optic B is selected based upon desire pump profile characteristics resulting from the optical effect of the geometry of the laser medium body C. The index of refraction, surface curvature and distance of transmissive optic B is relative to the laser pump A and the laser medium body C. The transmissive optic B optical properties and distance will depend upon the cross-sectional shape of the laser medium body C and the mode size desired within the laser medium body C with consideration given to any space constraints.

Spacing of the reflector D relative to the laser medium body C and its shape is initially designed such that the backward propagating rays are incident within the laser medium body C. A portion of the pump light which is incident on the reflector D may be reflected such that ancillary reflectors E direct the residual pump light along the vertical axis forming a more complete laser mode overlap.

Furthermore, an axis of the emitter elements 23′ (only one element is shown in the diagram as the emitter axis is in and out of the page) may be skewed or titled relative to the laser axis to effect a broader vertical distribution of energy for greater mode-filling properties, particularly along the axis perpendicular to the axis formed by the pump laser 22′. To optimize symmetry in the laser medium body C, the laser medium body C should have absorption properties conducive for creating an even distribution of absorbed energy on either side of the laser axis.

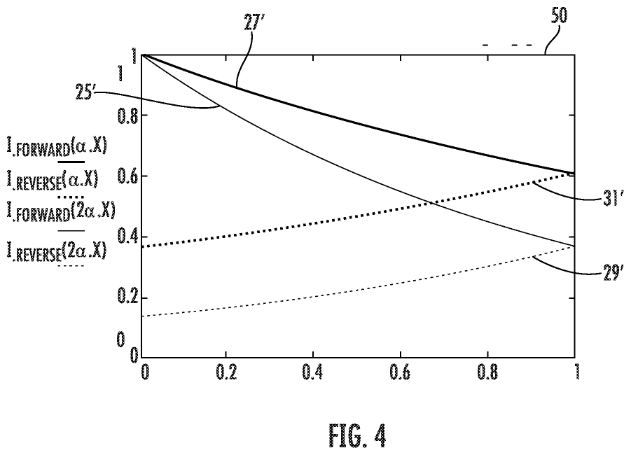

Referring now to FIG. 4, a plot 50 of normalized intensity for forward and backward round-trip propagation within the laser medium body C for two different pump absorption values is provided. The solid line 25′ represents forward propagation along the longitudinal axis in the laser medium body C, and the corresponding dashed line 29′ represents the recirculation path for reverse propagation. The solid line 27′ represents forward propagation for the marginal rays in the laser medium body C, and the corresponding dashed line 31′ represents the recirculation path for reverse propagation.

The y-axis is transmission of the beam, and the x-axis is the width of the laser medium body C. The plot 50′ demonstrates the effect of absorption of the beam within the laser medium C as the beam propagates through a width of the laser medium body C.

More particularly, the plot shows the width normalized round-trip pump absorption versus propagation distance in the laser medium body C for absorption coefficients of ∀=0.5 and 1.0. In both cases, there is residual energy for a round-trip through an arbitrary absorbing medium.

As can be demonstrated, strong absorption will lead to greater asymmetry in one-sided pump absorption, whereas weak absorption will lead to greater symmetry. However, for the weaker absorption case the pump light may make more round-trips through the laser medium body C for it to be absorbed at an amount comparable to the stronger absorption case. In this latter case, alignment and reflectivities of the pump recirculating elements may need to be considered more strongly.

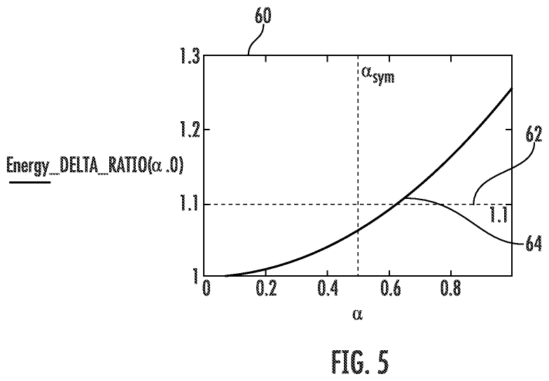

Referring now to FIG. 5, a plot 60 of a figure-of-merit for asymmetric pump absorption is provided. A ratio of forward to backward propagating pump absorption on either side of the laser axis (y-axis) is given as a function of the absorption coefficient ∀ (x-axis). A notional limit of 1.1 corresponding to dashed line 62 is displayed on the plot 60 indicating the absorption coefficient ∀ should be no larger than approximately 0.6 corresponding to point 64.

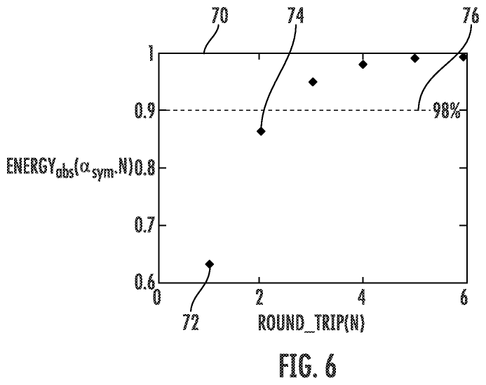

Referring now to FIG. 6, a plot 72 showing the pump energy absorbed versus a number of round-trips through the laser medium body B is provided. Diamond 72 represents 1 round-trip whereas diamond 74 represents 2 round-trips. The number of round-trips incrementally increase with the remaining diamonds.

An arbitrary figure of merit of 90%, as represented by dashed line 76, is such that the maximum number of round-trips through the laser medium body C should be managed. In the plot 70, 2 round-trips should be managed for high efficiency. The pump optical system design may need to be configured in such a way as to avoid recirculating the pump light into the laser pump A.

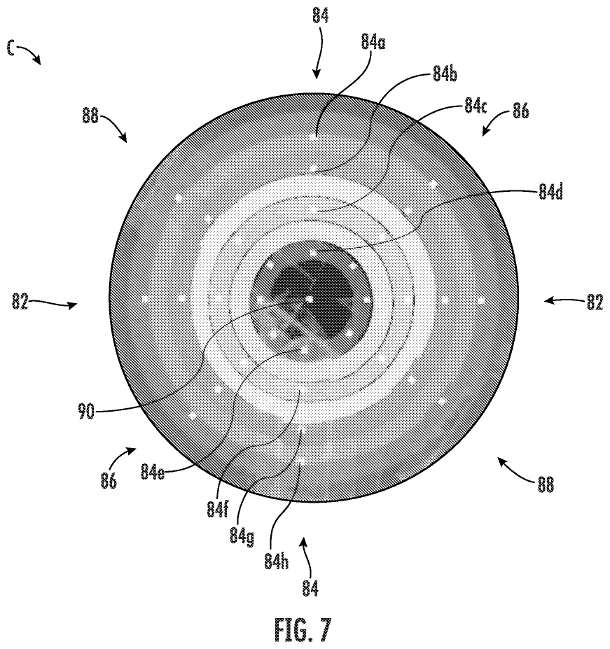

Referring now to FIG. 7, an enlarged cross-sectional view of the laser medium body C as shown in FIG. 3 depicts a radially-symmetric and intensity varying pump mode. Each concentric ring in the cross-section represents a respective intensity of the desired laser spatial mode.

The center ring has the highest intensity value and the outermost ring has the lowest intensity value. The intensity values of the middle rings incrementally decrease between the highest and lowest intensity values.

As noted above, the merit function includes target absorption values defining a desired symmetrical absorption profile of the laser beam passing through the laser medium body C. In particular, the target absorption values represent an absorbed flux of the laser beam passing through the laser medium body C.

In the cross-sectional view, a plurality of points illustrated as squares are spread uniformly over different axes of the mode profile. Point 90 is in the center of the cross-sectional view. There are points are along the horizontal axis 82, the vertical axis 84, and a pair of diagonal axes 86 and 88. The vertical axis 84, for example, includes points 84a-84h. Although not labeled, the points on the horizontal axis 82 and the diagonal axes 86, 88 are uniformly spaced and would have similar reference markings for each respective axis. Additional points may be added to further define the desired laser mode for greater radial symmetry.

Each point is assigned a discrete target absorption value. Collectively, the discrete target absorption values define the desired symmetrical absorption profile. For greater resolution, additional points may be added resulting in additional calculations by the optical model.

The resultant symmetrical absorption profile may appear as a bow tie shape within the cross-sectional view 80, for example. The absorbed flux values of the points are selected to generally define a smooth radially-symmetric profile.

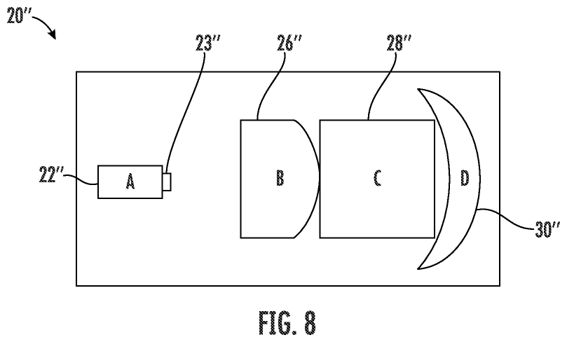

For illustration purposes, the desired symmetrical absorption profile is to be obtained using the resonator components for the single-sided pumped laser device 20″ illustrated in cross-section in FIG. 8. The resonator components include the laser pump A, the transmissive optic B, the laser medium C and the reflector D. The optical model uses the merit function to correct for pump light distribution asymmetry by determining tilts, spacings and surface shape modifications of these resonator components.

A starting point is to determine the initial relative spacings among the resonator components, as reflected by positioning of the resonator components in FIG. 8. Determination of the adjusted relative spacings will be constrained by the size of the device that is to include the single-sided pumped laser device 20″, such as a hand-held laser rangefinder.

The laser medium body C is to have a rectangular shape with an absorption coefficient of 0.50. The divergence angles of the pump light from the laser pump A has a fast axis divergence angle of 30 degrees, and a slow axis divergence angle of 10 degrees. The divergence angles are full width at half maximum (FWHM), single mode.

The optical model determines a plurality of computed absorption profiles, with each computed absorption profile comprising a plurality of computed absorption values corresponding to the plurality of target absorption values. In other words, absorbed flux values for the points in FIG. 7 are calculated by the optical model for computed absorption values.

The optical model determines the plurality of computed absorption profiles while varying curvature of the transmissive optic B and the reflector D, and varying relative spacings among the laser medium body C, the laser pump B, the transmissive optic B and the reflector D.

The merit function compares, for each computed absorption profile, the plurality of computed absorption values to the plurality of target absorption values. The merit function is computed as follows:

$${MF}^{2} = \frac{\sum {{W}_{i} ( {V}_{i} - {T}_{i} )}^{2}}{\sum {W}_{i}}$$

Wᵢ is the weight of an i^{th} operand, Vᵢ is its computed absorption value, and Tᵢ is the corresponding target absorption value. The summation is over all of the operands in the merit function. As the computed absorption values of the operands move towards their target absorption values, the function value approaches zero. Because the difference between the target absorption values T and the computed absorption values V of each operand is squared, any deviation from the target absorption value yields an increasingly positive value of the merit function.

The merit function determines, for each computed absorption profile, a difference between the plurality of computed absorption values and the corresponding plurality of target absorption values, with the differences for each computed absorption profile being summed together to define a respective merit function value.

The optical model defines a plurality of respective merit function values ranging from high to low. A goal of the optical model is to reduce the merit function to 0, or as close as possible, by varying curvature of the transmissive optic B and the reflector D, and varying relative spacings among the laser medium body C, the laser pump B, the transmissive optic B and the reflector D.

TABLE 1

| | | | | Index Of | |
|---|---|---|---|---|---|
| | Position | | | Refraction | |
| | Relative To | Half | | Relative To | Thick- |
| Element | Center Of C | Height | Surface Radii | Air = 1 | ness |
| A | −4.108 | N/A | N/A | N/A | N/A |
| B | −2.333 | 1 | Infinity/1.449 | 1.509 | 1.333 |
| C | 0 | 1 | Infinity | N/A | N/A |
| D | 1.349 | 1.333 | 1.941 | N/A | N/A |

Example dimensionless curvatures and relative spacing values as have been determined by the optical model optimization are provided above in TABLE 1. The resonator elements A-D are listed in the first column. The second column provides the relative spacings for the resonator components. The spacings are relative to the center of the laser medium body C. The third column provides the half-height of elements B, C and D. The half-heights are provided for compatibility with ray-tracing optical software ray clearance requirements.

The curvature of elements B and D are provided in the fourth column. Since element C has a rectangular shape, the curvature is listed as infinity which corresponds to a flat surface. For element B, one side is flat and the opposing side has a curvature radius of 1.449. The curvature of element D has a curvature radius of 1.941. The fifth column provides the index of refraction for element B. In the last column, a thickness of element B is provided.

The resonator components for the single-sided pumped laser device 20″ are to be assembled using the curvature of the transmissive optic B and the reflector D based on TABLE 1, and the adjusted relative spacings among the laser medium body C, the laser pump B, the transmissive optic B and the reflector D as also based on TABLE 1. In other embodiments, rotating or tilting of the resonator components may also be taken into consideration by the optical model.

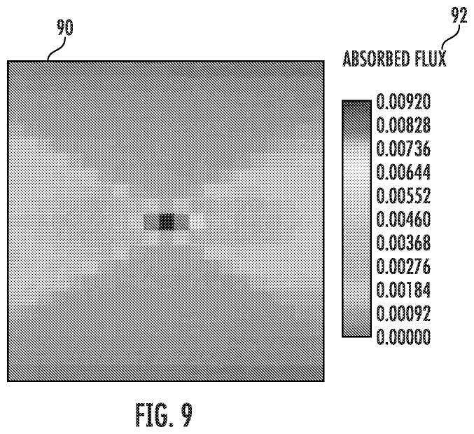

Referring now to FIG. 9, a plot 90 of the absorbed flux for the laser medium body C after operating the optical model based on the merit function is provided. Next to the plot 90 are corresponding absorbed flux values 92. The absorbed flux is based on a linear scale with arbitrary units. The pump light distribution within the laser medium body C has a bow tie shape that is symmetrical with respect to the longitudinal axis.

The pump absorption asymmetry along the horizontal axis for this configuration is 1.68 using the definition of (LH−RH)/(2*(LH+RH), where LH is all summed absorbed flux to the left of the center of the laser medium body C and RH is all absorbed flus to the right of the laser medium body C. By design, the vertical axis is symmetrical.

Another aspect is directed to a non-transitory computer readable medium for operating a computing device comprising a display and processor coupled to the display, and with the non-transitory computer readable medium having a plurality of computer executable instructions for causing the processor to perform a series of steps. The steps include receiving as input an absorption coefficient for a laser medium body 28, and receiving as input divergence angles of pump light 24 from a laser pump 22 to be directed at a side of the laser medium body 28.

The steps further include receiving as input initial relative spacings of at least one reflector 30 for the pump light with respect to the laser medium body 28 and the laser pump 22, and receiving as input a merit function defining a desired absorption profile of the pump light passing through the laser medium body 28.

An optical model is operated based on the received merit function and the received absorption coefficient, divergence angles and initial relative spacings to determine a curvature of the at least one reflector 30, adjusted relative spacings among the laser medium body 28, the laser pump 22, and the at least one reflector 30. The determined curvature of the at least one reflector 30 and the adjusted relative spacings to be used are displayed to make the single-sided pumped laser device 20.

Many modifications and other embodiments will come to the mind of one skilled in the art having the benefit of the teachings presented in the foregoing descriptions and the associated drawings. Therefore, it is understood that the foregoing is not to be limited to the example embodiments, and that modifications and other embodiments are intended to be included within the scope of the appended claims.

1. A method for making a single-sided pumped laser device comprising:
determining an absorption coefficient for a laser medium body;
determining divergence angles of pump light from a laser pump to be directed at a side of the laser medium body;
determining initial relative spacings of at least one reflector for the pump light with respect to the laser medium body and the laser pump;
generating a merit function defining a desired absorption profile of the pump light passing through the laser medium body;
using a processor and an associated memory to operate an optical model based on the merit function and the determined absorption coefficient, divergence angles and initial relative spacings to determine the following:
a curvature of the at least one reflector, and
adjusted relative spacings among the laser medium body, the laser pump, and the at least one reflector; and
assembling the laser medium body, the laser pump, and the at least one reflector according to the determined curvature of the at least one reflector and the adjusted relative spacings to make the single-sided pumped laser device.

2. The method according to claim 1 wherein the merit function comprises a plurality of target absorption values defining the desired absorption profile.

3. The method according to claim 2 wherein the optical model determines a plurality of computed absorption profiles, with each computed absorption profile comprising a plurality of computed absorption values corresponding to the plurality of target absorption values.

4. The method according to claim 3 wherein the optical model determines the plurality of computed absorption profiles while varying curvature of the at least one reflector and varying relative spacings among the laser medium body, the laser pump and the at least one reflector.

5. The method according to claim 3 wherein the merit function compares, for each computed absorption profile, the plurality of computed absorption values to the plurality of target absorption values.

6. The method according to claim 5 wherein the merit function determines, for each computed absorption profile, a difference between the plurality of computed absorption values and the corresponding plurality of target absorption values, with the differences for each computed absorption profile being summed together to define a respective merit function value.

7. The method according to claim 6 wherein the optical model defines a plurality of respective merit function values ranging from high to low, with the single-sided pumped laser device being assembled using the curvature of the at least one reflector and the relative spacings among the laser medium body, the laser pump and the at least one reflector for the merit function value having the lowest value.

8. The method according to claim 1 wherein the laser pump comprises a laser diode.

9. The method according to claim 1 wherein the laser medium body comprises one of a laser rod having a cylindrical shape, a laser slab having a rectangular shape, and a hybrid combination of the laser rod and the laser slab.

10. The method according to claim 1 wherein the single-sided pumped laser device is configured to operate within a laser range finder.

11. The method according to claim 1 wherein the desired absorption profile for pump wavelengths of the pump light is symmetrical to a centerline of the laser medium body.

12. A method for making a single-sided pumped laser device comprising:
determining initial relative spacings of at least one reflector with respect to a laser medium body having an known absorption coefficient, and to a laser pump having known divergence angles of pump light to be directed at a side of the laser medium body;
generating a merit function comprising a plurality of target absorption values defining a desired absorption profile of the pump light passing through the laser medium body;
using a processor and an associated memory to operate an optical model to perform the following:
determine a plurality of computed absorption profiles, with each computed absorption profile comprising a plurality of computed absorption values corresponding to the plurality of target absorption values while varying curvature of the at least one reflector and varying relative spacings among the laser medium body, the laser pump and the at least one reflector, and
operate the merit function, for each computed absorption profile, to compare the plurality of computed absorption values to the plurality of target absorption values to define a plurality of respective merit function values, and
compare the respective merit function values to select the one that more closely corresponds to the desired absorption profile; and
assembling the single-sided pumped laser device using the curvature of the at least one reflector and the relative spacings among the laser medium body, the laser pump and the at least one reflector corresponding to the selected merit function value.

13. The method according to claim 12 wherein the merit function determines, for each computed absorption profile, a difference between the plurality of computed absorption values and the corresponding plurality of target absorption values, with the differences for each computed absorption profile being summed together to define a respective merit function value.

14. The method according to claim 13 wherein the optical model defines a plurality of respective merit function values ranging from high to low, with the single-sided pumped laser device being assembled using the curvature of the at least one reflector and the relative spacings among the laser medium body, the laser pump and the at least one reflector for the merit function value having the lowest value.

15. The method according to claim 12 wherein the laser pump comprises a laser diode.

16. The method according to claim 12 wherein the laser medium body comprises at least one of a laser rod having a cylindrical shape, a laser slab having a rectangular shape, and a hybrid combination of the laser rod and the laser slab.

17. The method according to claim 12 wherein the single-sided pumped laser device is configured to operate within a laser range finder.

18. The method according to claim 12 wherein the desired absorption profile is symmetrical to a centerline of the laser medium body.

19. A non-transitory computer readable medium for operating a computing device comprising a display and processor coupled to the display, and with the non-transitory computer readable medium having a plurality of computer executable instructions for causing the processor to perform steps comprising:
receiving as input an absorption coefficient for a laser medium body;
receiving as input divergence angles of pump light from a laser pump to be directed at a side of the laser medium body;
receiving as input initial relative spacings of at least one reflector for the pump light with respect to the laser medium body and the laser pump;
receiving as input a merit function defining a desired absorption profile of the pump light passing through the laser medium body; and
operating an optical model based on the received merit function and the received absorption coefficient, divergence angles and initial relative spacings to determine the following:
a curvature of the at least one reflector,
adjusted relative spacings among the laser medium body, the laser pump, and the at least one reflector, and
displaying the determined curvature of the at least one reflector and the adjusted relative spacings to be used to make a single-sided pumped laser device.

20. The non-transitory computer readable medium according to claim 19 wherein the desired absorption profile of the pump light is symmetrical to a centerline of the laser medium body.
